(19) United States
(12) Patent Application Publication
(10) Pub. No.: US 2024/0074162 A1
(43) Pub. Date: Feb. 29, 2024

(54) LANTHANUM NITRIDE AS A DRAM MOLYBDENUM LINER

(71) Applicant: Applied Materials, Inc., Santa Clara, CA (US)

(72) Inventors: Rand Haddadin, Gilbert, AZ (US); Kunal Bhatnagar, Chandler, AZ (US)

(73) Assignee: Applied Materials, Inc., Santa Clara, CA (US)

(21) Appl. No.: 17/898,796

(22) Filed: Aug. 30, 2022

(51) Int. Cl. H01L 27/108; H01L 21/285; H01L 21/768; H01L 23/522; H01L 23/528; H01L 23/532

(52) U.S. Cl. CPC H01L 27/10891; H01L 21/28568; H01L 21/76846; H01L 23/5226; H01L 23/5283; H01L 23/53266

(57) ABSTRACT

Methods for DRAM device with a buried word line are described. The method includes forming a metal nitride layer comprising lanthanum nitride (LaN) and a molybdenum conductor layer in a feature on a substrate. The method includes depositing the molybdenum conductor layer by atomic layer deposition (ALD) on the metal nitride layer.

### TECHNICAL FIELD

Embodiments of the disclosure pertain to the field of semiconductor devices and semiconductor device manufacturing. More particularly, embodiments of the disclosure are directed to methods of which utilize lanthanum nitride as a liner for DRAM molybdenum applications.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with non-array devices. The formation of a low resistance contact between the active area and the 3D DRAM bottom electrode is essential for performance of the device.

In DRAM devices, one of the main goals is to increase storage per unit space, which results in an increase of the vertical dimensions or the stack height of the DRAM devices. The vertical-cell DRAM has the advantage of reducing the chip area by about one third compared with the conventional cell DRAM. Accordingly, there is a need for 3D DRAM devices and methods of manufacture that do not result in a floating body access transistor and that do not increase the area of the cell.

### SUMMARY

One or more embodiments of the disclosure are directed to a method of forming a buried word line. In one or more embodiments, the method comprises: depositing a metal nitride layer on a substrate, the metal nitride layer comprising lanthanum nitride; and depositing a molybdenum conductor layer by an atomic layer deposition (ALD) process on the metal nitride layer.

In one or more embodiments, a method of forming a buried word line comprises depositing a metal nitride layer on a substrate, the metal nitride layer comprising lanthanum nitride; and depositing a molybdenum conductor layer by an atomic layer deposition (ALD) process on the metal nitride layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method according to one or more embodiment of the disclosure;

FIGS. 2A-2D illustrate cross-section views of a device according to one or more embodiments;

FIGS. 3A-3C illustrate cross-section views of a device according to one or more embodiments;

FIGS. 4A-4D illustrate cross-section views of a device according to one or more embodiments; and

FIGS. 5A-5C illustrate cross-section views of a device according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used in this specification and the appended claims, the terms “precursor,” “reactant,” “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time-delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

As used herein throughout the specification, “substantially simultaneously” means that most of the duration of the first reactive compound exposure overlaps with the second reactive compound exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the purging the substrate surface or the reaction chamber may occur for a time duration in a range of from 0.2 seconds to 30 seconds, from 0.2 seconds to 10 seconds, from 0.2 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells. The rows on access transistors are linked by word lines, and the transistor inputs/outputs are linked by bit lines. Historically, DRAM capacitors have evolved from planar polysilicon-oxide-substrate plate capacitors to 3-D structures which have diverged into “stack” capacitors with both plates above the substrate, and “trench” capacitors using an etched cavity in the substrate as the common plate.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In a buried word line (bWL) device, a word line is buried below the surface of a semiconductor substrate using a metal as a gate electrode. Current DRAM buried word line (bWL) processes involve titanium nitride (TiN) as a liner and tungsten (W) stacks or molybdenum (Mo) stacks. The stack can have high resistivity, high effective work function (eWF), and poor equivalent oxide thickness (EOT)/interface trap densities (DiT). Accordingly, embodiments of the present disclosure advantageously provide an alternative liner material, lanthanum nitride (LaN), for molybdenum (Mo) stacks in a DRAM buried word line (bWL) on a substrate which reduces resistance in the DRAM device.

In one or more embodiments, a resistance (μΩ-cm) is measured for the buried word line having a total thickness of 100 Å. In one or more embodiments, the buried word line has a resistance less than or equal to 40 μΩ-cm, less than or equal to 30 μΩ-cm, less than or equal to 25 μΩ-cm, or less than or equal to 20 μΩ-cm, or less than or equal to 15 μΩ-cm at a total thickness of 100 Å. In some embodiments, the buried word line has resistance less than or equal to 20 μΩ-cm at a total thickness of 100 Å. In one or more embodiments, the buried word line formed by the method 100 has a resistance in a range of from 50 μΩ-cm to 5 μΩ-cm, from 40 μΩ-cm to 10 μΩ-cm, from 30 μΩ-cm to 10 μΩ-cm, from 25 μΩ-cm to 10 μΩ-cm, from 20 μΩ-cm to 10 μΩ-cm at a total thickness of 100 Å.

The embodiments of the disclosure are described by way of the Figures, which illustrate devices (e.g., transistors, memory devices, and the like) and processes for forming the devices in accordance with one or more embodiments of the disclosure. The processes shown are merely illustrative possible uses for the disclosed processes, and the skilled artisan will recognize that the disclosed processes are not limited to the illustrated applications.

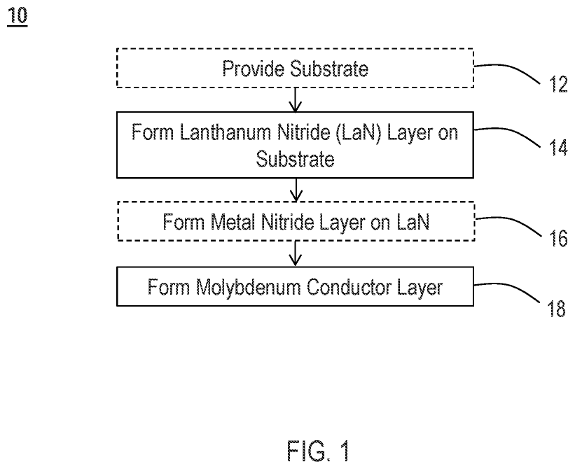

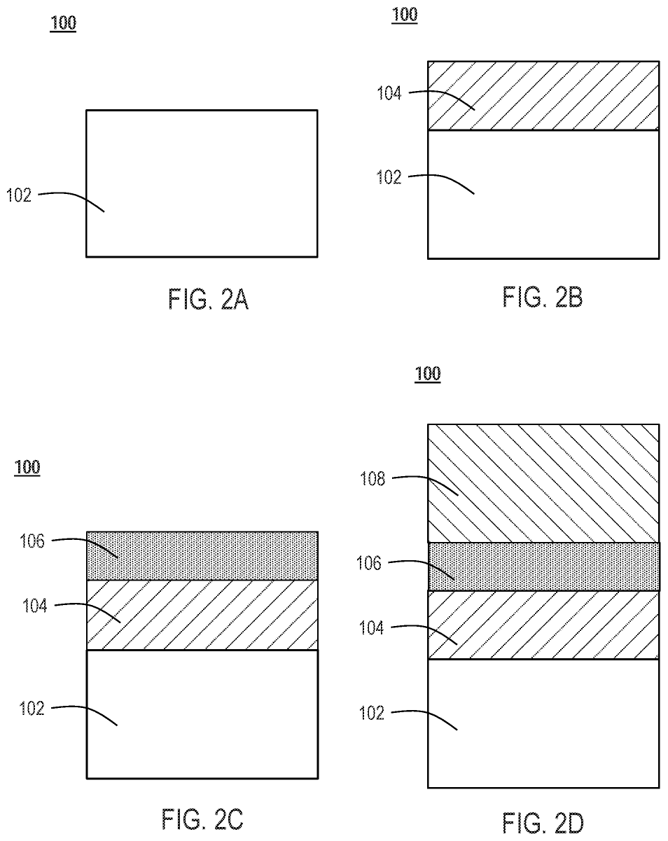

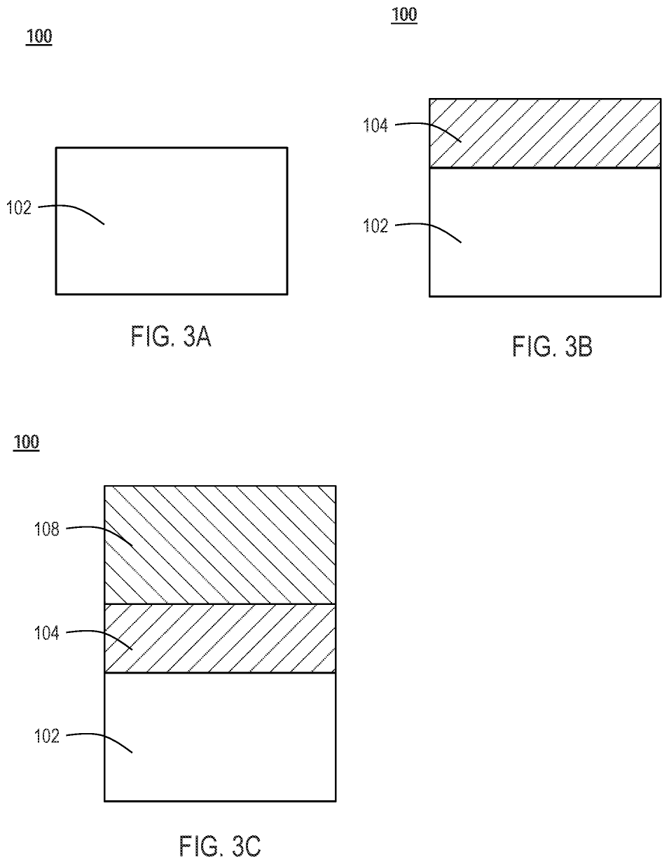

One or more embodiments of the disclosure are described with reference to the Figures. FIG. 1 illustrates a process flow diagram of a method according to one or more embodiments of the present disclosure. FIGS. 2A through 3D are cross-sectional views illustrating a memory device 100 in various stages of processing to form a buried word line (bWL) according to one or more embodiments.

With reference to FIG. 1, one or more embodiments of the disclosure are directed to method 10 of forming a memory device, e.g., a buried word line (bWL). At operation 12, a substrate is provided. At operation 14, a metal nitride layer comprising lanthanum nitride is formed on the substrate. At operation 16, a second metal nitride layer is optionally formed on the metal nitride layer. At operation 18, a molybdenum conductor layer is formed on the metal nitride layer.

Referring to FIGS. 2A to 3C, a substrate 102 is provided for processing. As used in this regard, the term “provided” means that the substrate is placed into a position or environment for further processing.

In one or more embodiments, the substrate 102 can be any suitable substrate material. In one or more embodiments, the substrate 102 comprises one or more of silicon oxynitride (SiON), silicon oxide (SiOₓ), or a high-K dielectric material. While the term “silicon oxide” may be used to describe the substrate 102, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. The same is true for the other materials listed in this disclosure, e.g., silicon nitride, silicon oxynitride, tungsten oxide, zirconium oxide, aluminum oxide, hafnium oxide, and the like. Although a few examples of materials from which the substrate 102 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the substrate 102 can have any suitable thickness known to the skilled artisan. In some embodiments, the substrate 102 has a thickness in a range of from 20 Å to 100 Å, including in a range of from 30 Å to 75 Å, including in a range of from 40 Å to 60 Å.

In one or more embodiments, as illustrated in FIGS. 2B and 3B, a metal nitride layer 104 is formed on the surface of the substrate 102. The metal nitride layer 104 may comprise any suitable material known to the skilled artisan. In one or more embodiments, the metal nitride layer 104 comprises lanthanum nitride (LaN).

The metal nitride layer 104 may have any suitable thickness. In one or more embodiments, the metal nitride layer 104 has a thickness of less than 20 Å. In one or more embodiments, the metal nitride layer 104 has a thickness in a range of from about 1 Å to less than about 20 Å, including in a range of from 5 Å to 20 Å, including in a range of from 5 Å to 15 Å, including in a range of from 10 Å to 20 Å, and including in a range of from 10 Å to 15 Å. In one or more embodiments, a metal nitride layer 104 is formed comprising lanthanum nitride (LaN) having a thickness in a range of about 10 Å to about 15 Å.

In one or more embodiments, referring to FIG. 2C, a second metal nitride layer 106 is optionally formed on the surface of the metal nitride layer 104. The second metal nitride layer 106 may comprise any suitable material known to the skilled artisan. In one or more embodiments, the second metal nitride layer 106 comprises one or more of titanium nitride (TiN), tantalum nitride (TaN), yttrium nitride (YN), zirconium nitride (ZrN), hafnium nitride (HfN), and barium nitride (BaN). In one or more specific embodiments, the second metal nitride layer 106 comprises titanium nitride (TiN). It is noted that FIGS. 3A to 3C illustrate an alternative embodiment, where the second metal nitride layer 106 is absent and only the first metal nitride layer 104 is present on the substrate 102 surface.

The second metal nitride layer 106 may have any suitable thickness. In one or more embodiments, the second metal nitride layer 106 has a thickness in a range of about 0.1 nm to about 10 nm, including in a range of from 5 nm to 8 nm, including in a range of from 1 nm to 3 nm, including in a range of from 1 nm to 2 nm. In one or more embodiments, the second metal nitride layer 106 is formed comprising titanium nitride (TiN) having a thickness in a range of about 1 nm to about 2 nm.

In one or more embodiments, the first metal nitride layer 104 and the second metal nitride layer 106 have a combined thickness of about 30 Å, including in a range of from 15 Å to about 30 Å.

In one or more embodiments, the molybdenum conductor 108 is formed by atomic layer deposition. The atomical layer deposition may be a thermal process. With reference to FIG. 2D, the device 100 is exposed to a molybdenum precursor to deposit a molybdenum conductor layer 108 on the second metal nitride layer 106. With reference to FIG. 3C, the device 100 is exposed to a molybdenum precursor to deposit the molybdenum conductor layer 108 on the metal nitride layer 104. The molybdenum precursor can be any suitable molybdenum-containing compound that can react with (i.e., adsorb or chemisorb onto) the metal nitride layers 104, 106 to leave a molybdenum-containing species on the surface.

In one or more embodiments, the molybdenum precursor comprises any suitable precursor known to the skilled artisan. The molybdenum precursors of one or more embodiments are volatile and thermally stable, and, thus, suitable for vapor deposition. In some embodiments, the molybdenum precursor comprises a molybdenum halide. As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—). Accordingly, as used herein, the term “molybdenum halide” refers to any coordination complex of molybdenum with one or more halogen or halide ligand. The term molybdenum halide includes molybdenum mixed halides which have at least two different halide atoms.

In one or more embodiments, the molybdenum halide is selected from one or more of molybdenum chloride, molybdenum pentachloride, molybdenum bromide, molybdenum iodide, molybdenum bromochloride, molybdenum bromoiodide, molybdenum chlorobromide, molybdenum chloroiodide, molybdenum iodobromide, molybdenum iodochloride.

In some embodiments, the molybdenum precursor comprises a molybdenum oxyhalide species. In some embodiments, the molybdenum oxyhalide species comprises one or more of molybdenum tetrachloride oxide (MoCl₄O), molybdenum tetrabromide oxide (MoBr₄O), molybdenum tetraiodide oxide (MoI₄O), molybdenum dibromide dioxide (MoO₂Br₂), molybdenum dichloride dioxide (MoCl₂O₂), and/or molybdenum diiodide dioxide (MoI₂O₂).

In one or more specific embodiments, the molybdenum precursor comprises one or more of molybdenum chloride (MoCl₅), molybdenum fluoride (MoF₆), molybdenum iodide (MoI₆), molybdenum bromide (MoBr₃), molybdenum hexacarbonyl (Mo(CO)₆), molybdenum dichloride dioxide (MoO₂Cl₂), molybdenum oxytetrachloride (MoOCl₄), tetrakis(dimethylamino)molybdenum(IV), and bis(tert-butylimido)-bis(dimethylamido)molybdenum.

In some embodiments, the metal nitride layer 104, 106 is exposed to the molybdenum precursor at a temperature in a range of from 350° C. to 550° C., from 400° C. to 550° C., from 450° C. to 550° C., 500° C. to 550° C., from 350° C. to 500° C., from 400° C. to 500° C., from 450° C. to 500° C., from 350° C. to 450° C., from 400° C. to 450° C. or from 350° C. to 400° C.

In some embodiments, the metal nitride layer 104, 106 is exposed to the molybdenum precursor for a duration of time in a range of from 0.25 seconds to 20 minutes, from 10 seconds to 20 minutes, from 1 minutes to 20 minutes, from 5 minutes to 20 minutes, from 10 minutes to 20 minutes, from 0.25 seconds to 10 minutes, from 10 seconds to 10 minutes, from 1 minutes to 10 minutes, from 5 minutes to 10 minutes, from 0.25 seconds to 5 minutes, from 10 seconds to 5 minutes, from 1 minutes to 5 minutes, from 0.25 seconds to 1 minutes or from 10 seconds to 1 min.

In some embodiments, the metal nitride layer 104, 106 is exposed to the molybdenum precursor at a dose in a range of from 50 sccm to 700 sccm, from 100 sccm to 700 sccm, from 300 sccm to 700 sccm, from 500 sccm to 700 sccm, from 50 sccm to 500 sccm, from 100 sccm to 500 sccm, from 300 sccm to 500 sccm, from 50 sccm to 300 sccm, from 100 sccm to 300 sccm or from 50 sccm to 100 sccm.

In some embodiments, the metal nitride layer 104, 106 is exposed to the molybdenum precursor at a pressure in a range of from 5 Torr to 50 Torr, from 10 Torr to 50 Torr, from 25 Torr to 50 Torr, from 5 Torr to 25 Torr, from 10 Torr to 25 Torr or from 5 Torr to 10 Torr.

In some embodiments, the molybdenum conductor layer 108 formed comprises elemental molybdenum. In some embodiments, the molybdenum conductor layer 108 consists essentially of molybdenum. As used in this manner, the term “consists essentially of molybdenum” means that the content of molybdenum in the film is greater than or equal to about 80%, 85%, 90%, 95%, 98%, 99% or 99.5% molybdenum, in atomic percent. Measurements of the composition of the molybdenum conductor layer 108 refer to the bulk portion of the molybdenum conductor layer 108, excluding interface regions where diffusion of elements from adjacent films may occur.

Referring to FIGS. 2D and 3C, in some embodiments, the thickness of the molybdenum conductor layer 108 can be any suitable thickness. In some embodiments, the molybdenum conductor layer 108 has a thickness in the range of from 1 nm to 50 nm, from 5 nm to 50 nm, from 10 nm to 50 nm, from 25 nm to 50 nm, from 1 nm to 25 nm, from 5 nm to 25 nm, from 10 nm to 25 nm, from 1 nm to 10 nm, from 5 nm to 10 nm or from 1 nm to 5 nm.

With reference to FIGS. 1 and 4A through 5C, one or more embodiments of the disclosure are directed to method 10 of forming a memory device 200, e.g., a buried word line (bWL).

Referring to FIGS. 3A to 5C, in one or more embodiments, a substrate 202 is provided having a plurality of trenches 210 therein. The trenches 210 form a recessed channel. The trenches have a bottom 203 and at least one sidewall 207. The plurality of trenches 210 may be formed so as to have a width within a range of about 10 to about 100 nm, including, but not limited to a range of about 10 nm to about 80 nm, about 10 nm to about 70 nm, about 10 nm to about 60 nm, about 10 nm to about 50 nm, or about 10 nm to about 40 nm. As will be recognized by one of skill in the art, the width of the plurality of trenches 210 is defined by a distance Wi from one sidewall 207 to another sidewall 207. The plurality of trenches 210 may be formed so as to have a depth within a range of about 120 nm to about 250 nm, including, but not limited to a range of about 120 nm to about 150 nm, about 150 nm to about 200 nm, about 200 nm to about 250 nm, about 120 nm to about 200 nm, or about 150 nm to about 250 nm. As will be recognized by one of skill in the art, the depth of the plurality of trenches 210 is defined by the distance Di from the substrate surface 205 to the bottom 203 of the plurality of trenches 210.

One or more embodiments of the disclosure are directed to methods of depositing a film in high aspect ratio features. A high aspect ratio feature is a trench, via or pillar having a height:width ratio greater than or equal to about 10, 20, or 50, or more. In some embodiments, the film is deposited conformally on/in the high aspect ratio feature. As used in this manner, a conformal film has a thickness near the top of the feature that is in the range of about 80-120% of the thickness at the bottom of the feature.

In order to form the plurality of trenches 210, a buffer insulating layer (e.g., a silicon oxide layer, not illustrated) may be formed on the substrate surface 205, and/or a hard mask layer (e.g., a nitride layer, not illustrated) may be formed. Such techniques are well known to those skilled and the art, and, thus, are not illustrated.

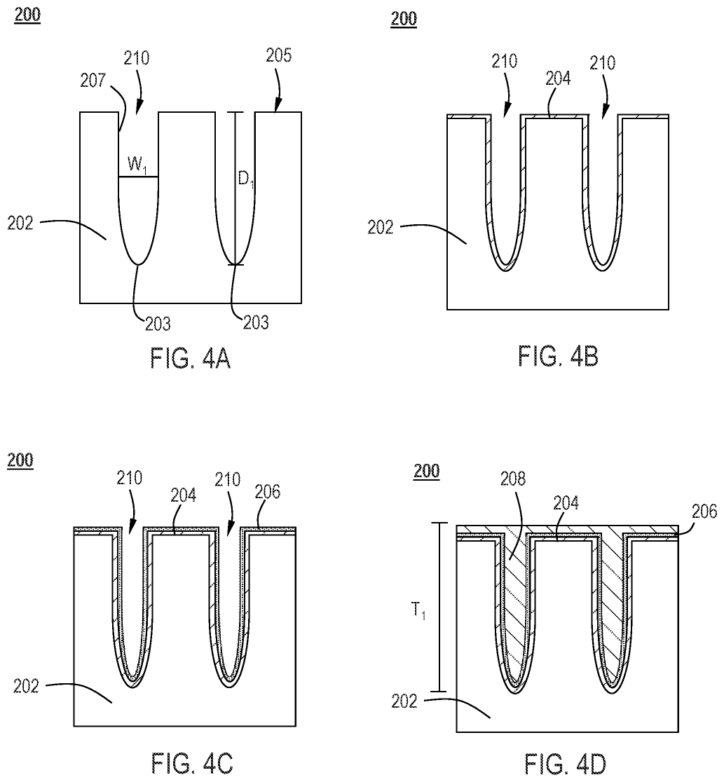

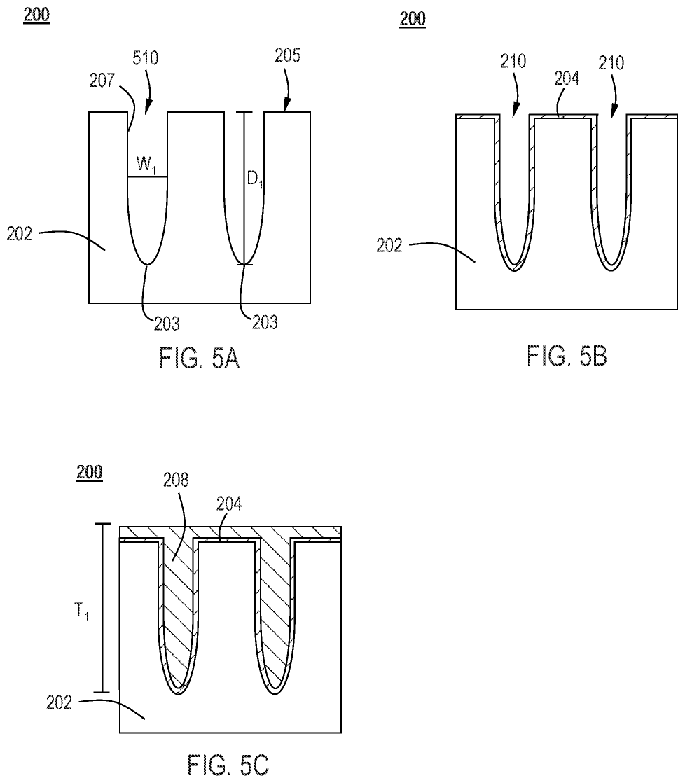

Referring to FIGS. 4B and 5B, in some embodiments, a metal nitride layer 204 is formed on the substrate 202. In one or more embodiments, the metal nitride layer 204 comprises any suitable metal nitride. In one or more embodiments, the metal nitride layer 204 comprises lanthanum nitride (LaN).

The metal nitride layer 204 may have any suitable thickness. In one or more embodiments, the metal nitride layer 204 has a thickness of less than 20 Å. In one or more embodiments, the metal nitride layer 204 has a thickness in a range of from about 1 Å to less than about 20 Å, including in a range of from 5 Å to 20 Å, including in a range of from 5 Å to 15 Å, including in a range of from 10 Å to 20 Å, and including in a range of from 10 Å to 15 Å. In one or more embodiments, a metal nitride layer 204 is formed comprising lanthanum nitride (LaN) having a thickness in a range of about 10 Å to about 15 Å.

In one or more embodiments, referring to FIG. 4C, a second metal nitride liner 206 is optionally formed on the surface of the metal nitride layer 204. The second metal nitride layer 206 may comprise any suitable material known to the skilled artisan. In one or more embodiments, the second metal nitride layer 206 comprises one or more of titanium nitride (TiN), tantalum nitride (TaN), yttrium nitride (YN), zirconium nitride (ZrN), hafnium nitride (HfN), and barium nitride (BaN). In one or more specific embodiments, the second metal nitride layer 206 comprises titanium nitride (TiN). It is noted that FIGS. 5A to 5C illustrate an alternative embodiment, where the second metal nitride layer 206 is absent and only the first metal nitride layer 204 is present on the substrate 202 surface.

The second metal nitride layer 206 may have any suitable thickness. In one or more embodiments, the second metal nitride layer 206 has a thickness in a range of about 0.1 nm to about 5 nm, including in a range of from 1 nm to 3 nm, including in a range of from 1 nm to 2 nm. In one or more embodiments, the second metal nitride layer 206 is formed comprising titanium nitride (TiN) having a thickness in a range of about 1 nm to about 2 nm.

In one or more embodiments, the molybdenum conductor 208 is formed by atomic layer deposition. The atomical layer deposition may be a thermal process. With reference to FIG. 4D, a process is performed to deposit a molybdenum conductor layer 204 on the substrate 202 (substrate surface). The deposition process can include one or more operations to form the molybdenum conductor layer 204 on the substrate 202. In some embodiments, the deposition process is selective for deposition on the metal nitride layer 204. With reference to FIG. 5C, a process is performed to deposit a molybdenum conductor layer 204 on the substrate 202 (substrate surface). The deposition process can include one or more operations to form the molybdenum conductor layer 204 on the substrate 202. In some embodiments, the deposition process is selective for deposition on the second metal nitride layer 206.

The molybdenum precursor can be any suitable molybdenum-containing compound that can react with (i.e., adsorb or chemisorb onto) the metal nitride layers 204, 206 to leave a molybdenum-containing species on the surface. The atomic layer deposition process of some embodiments comprises sequential exposures to a precursor and a reactant. The substrate 202 (or substrate surface) is optionally exposed to a reactant. In some embodiments, the reactant comprises a reducing agent. The reducing agent may be any suitable compound known to a skilled in the art. In some embodiments, the reducing agent comprises hydrogen (H₂).

In one or more embodiments, the molybdenum precursor comprises any suitable precursor known to the skilled artisan. The molybdenum precursors of one or more embodiments are volatile and thermally stable, and, thus, suitable for vapor deposition. In some embodiments, the molybdenum precursor comprises a molybdenum halide. As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—). Accordingly, as used herein, the term “molybdenum halide” refers to any coordination complex of molybdenum with one or more halogen or halide ligand. The term molybdenum halide includes molybdenum mixed halides which have at least two different halide atoms.

In one or more embodiments, the molybdenum halide is selected from one or more of molybdenum chloride, molybdenum pentachloride, molybdenum bromide, molybdenum iodide, molybdenum bromochloride, molybdenum bromoiodide, molybdenum chlorobromide, molybdenum chloroiodide, molybdenum iodobromide, molybdenum iodochloride.

In some embodiments, the molybdenum precursor comprises a molybdenum oxyhalide species. In some embodiments, the molybdenum oxyhalide species comprises one or more of molybdenum tetrachloride oxide (MoCl₄O), molybdenum tetrabromide oxide (MoBr₄O), molybdenum tetraiodide oxide (MoI₄O), molybdenum dibromide dioxide (MoO₂Br₂), molybdenum dichloride dioxide (MoCl₂O₂), and/or molybdenum diiodide dioxide (MoI₂O₂).

In one or more specific embodiments, the molybdenum precursor comprises one or more of molybdenum chloride (MoCl₅), molybdenum fluoride (MoF₆), molybdenum iodide (MoI₆), molybdenum bromide (MoBr₃), molybdenum hexacarbonyl (Mo(CO)₆), molybdenum dichloride dioxide (MoO₂Cl₂), molybdenum oxytetrachloride (MoOCl₄), tetrakis(dimethylamino)molybdenum(IV), and bis(tert-butylimido)-bis(dimethylamido)molybdenum.

In some embodiments, the metal nitride layer 204, 206 is exposed to the molybdenum precursor at a temperature in a range of from 350° C. to 550° C., from 400° C. to 550° C., from 450° C. to 550° C., 500° C. to 550° C., from 350° C. to 500° C., from 400° C. to 500° C., from 450° C. to 500° C., from 350° C. to 450° C., from 400° C. to 450° C. or from 350° C. to 400° C.

In some embodiments, the metal nitride layer 204, 206 is exposed to the molybdenum precursor for a duration of time in a range of from 0.25 seconds to 20 minutes, from 10 seconds to 20 minutes, from 1 minutes to 20 minutes, from 5 minutes to 20 minutes, from 10 minutes to 20 minutes, from 0.25 seconds to 10 minutes, from 10 seconds to 10 minutes, from 1 minutes to 10 minutes, from 5 minutes to 10 minutes, from 0.25 seconds to 5 minutes, from 10 seconds to 5 minutes, from 1 minutes to 5 minutes, from 0.25 seconds to 1 minutes or from 10 seconds to 1 min.

In some embodiments, the metal nitride layer 204, 206 is exposed to the molybdenum precursor at a dose in a range of from 50 sccm to 700 sccm, from 100 sccm to 700 sccm, from 300 sccm to 700 sccm, from 500 sccm to 700 sccm, from 50 sccm to 500 sccm, from 100 sccm to 500 sccm, from 300 sccm to 500 sccm, from 50 sccm to 300 sccm, from 100 sccm to 300 sccm or from 50 sccm to 100 sccm.

In some embodiments, the metal nitride layer 204, 206 is exposed to the molybdenum precursor at a pressure in a range of from 5 Torr to 50 Torr, from 10 Torr to 50 Torr, from 25 Torr to 50 Torr, from 5 Torr to 25 Torr, from 10 Torr to 25 Torr or from 5 Torr to 10 Torr.

Referring to FIGS. 4D and 5C, in one or more embodiments, the molybdenum conductor layer 208 may have any suitable thickness. For example, the molybdenum conductor layer 208 may have a thickness in a range of from 10 Å to 200 Å, from 20 Å to 200 Å, from 50 Å to 200 Å, from 100 Å to 200 Å, from 150 Å to 200 Å, from 10 Å to 150 Å, from 50 Å to 150 Å, from 100 Å to 150 Å, from 10 Å to 100 Å, from 50 Å to 100 Å, from 10 Å to 50 Å or from 10 Å to 30 Å.

Referring to FIGS. 4D and 5C, in some embodiments, the molybdenum conductor layer 208 is formed inside the feature 210. The molybdenum conductor layer 208 of some embodiments fills the gap formed by the feature in a bottom-up manner. As used in this manner, “bottom-up” means that the deposition occurs substantially on the bottom of the feature relative to the sidewalls.

In some embodiments, the molybdenum conductor layer 208 formed comprises elemental molybdenum. In some embodiments, the molybdenum conductor layer 108 consists essentially of molybdenum. As used in this manner, the term “consists essentially of molybdenum” means that the content of molybdenum in the film is greater than or equal to about 80%, 85%, 90%, 95%, 98%, 99% or 99.5% molybdenum, in atomic percent. Measurements of the composition of the molybdenum conductor layer 108 refer to the bulk portion of the molybdenum conductor layer 208, excluding interface regions where diffusion of elements from adjacent films may occur.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a buried word line, the method comprising:
depositing a metal nitride layer on a substrate, the metal nitride layer comprising lanthanum nitride; and
depositing a molybdenum conductor layer by an atomic layer deposition (ALD) process on the metal nitride layer.

2. The method of claim 1, wherein the metal nitride layer has a thickness of less than 20 Å.

3. The method of claim 1, further comprising depositing a second metal nitride layer on the metal nitride layer.

4. The method of claim 3, wherein the second metal nitride layer comprises one or more of titanium nitride (TiN), tantalum nitride (TaN), yttrium nitride (YN), zirconium nitride (ZrN), hafnium nitride (HfN), and barium nitride (BaN).

5. The method of claim 4, wherein the second metal nitride layer comprises titanium nitride.

6. The method of claim 1, wherein the ALD process is a thermal process.

7. The method of claim 1, wherein the molybdenum conductor layer is deposited selectively on the metal nitride layer.

8. The method of claim 1, wherein the ALD process comprises exposing the substrate sequentially to a reactant and a molybdenum precursor.

9. The method of claim 1, wherein the molybdenum conductor layer is deposited to a thickness in a range of from 10 Å to 200 Å.

10. The method of claim 1, wherein the ALD process occurs at a temperature in a range of 350° C. to 550° C.

11. The method of claim 1, wherein the buried word line has a resistance less than or equal to 20 μΩ-cm at a total thickness of 100 Å.

12. The method of claim 1, wherein the substrate has at least one feature having at least one sidewall and a bottom.

13. The method of claim 12, wherein the at least one feature has a width in a range of 10 nm to 12 nm.

14. The method of claim 12, wherein the at least one feature is filled with the molybdenum conductor layer in a bottom-up manner.

15. A method of forming a buried word line, the method comprising:
depositing a first metal nitride layer on a substrate, the first metal nitride layer comprising lanthanum nitride;
deposition a second metal nitride layer on the substrate; and
depositing a molybdenum conductor layer by an atomic layer deposition (ALD) process on the first metal nitride layer.

16. The method of claim 15, wherein the first metal nitride layer has a thickness of less than 20 Å.

17. The method of claim 15, wherein the second metal nitride layer comprises one or more of titanium nitride (TiN), tantalum nitride (TaN), yttrium nitride (YN), zirconium nitride (ZrN), hafnium nitride (HfN), and barium nitride (BaN).

18. The method of claim 15, wherein the first metal nitride layer and the second metal nitride layer have a combined thickness in a range of from 15 Å to 30 Å.

19. The method of claim 15, wherein the ALD process is a thermal process.

20. The method of claim 15, wherein the molybdenum conductor layer is deposited selectively on the second metal nitride layer.
